(19) United States
(12) Patent Application Publication
(10) Pub. No.: US 2005/0000442 A1
(43) Pub. Date: Jan. 6, 2005

(54) Upper electrode and plasma processing apparatus

(75) Inventors: Daisuke Hayashi, Nirasaki-shi (JP); Toshifumi Ishida, Nirasaki-shi (JP); Shigetoshi Kimura, Nirasaki-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 10/844,436

(22) Filed: May 13, 2004

(30) Foreign Application Priority Data
May 13, 2003 (JP) 2003-135093

(51) Int. Cl. C23C 16/00

(52) U.S. Cl. 118/723 E

(57) ABSTRACT

An upper electrode for use in generating a plasma of a processing gas includes a cooling block having a coolant path for circulating a coolant therethrough and one or more through holes for passing the processing gas therethrough, an electrode plate having one or more injection openings for injecting the processing gas toward the substrate to be processed mounted on the mounting table, and an electrode frame installed at an upper portion of the cooling block and providing a processing gas diffusion gap for diffusing the processing gas between the cooling block and the electrode frame. The electrode plate is detachably fixed to a bottom surface of the cooling block via a thermally conductive member having flexibility.

### FIELD OF THE INVENTION

The present invention relates to a plasma processing apparatus for performing a plasma process such as an etching process, a film forming process and the like by inducing a plasma to act on a substrate to be processed, e.g., a semiconductor wafer, a glass substrate for liquid crystal display (LCD) or the like; and an upper electrode employed therein.

### BACKGROUND OF THE INVENTION

Conventionally, a plasma processing apparatus for performing a process such as an etching process, a film forming process and the like by generating a plasma in a vacuum chamber and inducing the plasma to act on a substrate to be processed, e.g., a semiconductor wafer, a glass substrate for LCD or the like, has been widely used in a field of manufacturing semiconductor devices.

In such a plasma processing apparatus, e.g., a so-called parallel plate type plasma processing apparatus, a mounting table (a lower electrode) for mounting thereon a semiconductor wafer and the like is installed in a vacuum chamber, and provided at a ceiling portion thereof is an upper electrode facing the mounting table. The mounting table (the lower electrode) and the upper electrode form a pair of parallel plate electrodes.

In such a plasma processing apparatus, a processing gas ambient of predetermine vacuum level is attained in the vacuum chamber by introducing a predetermined processing gas into the vacuum chamber, while evacuating the vacuum chamber through a bottom portion thereof, during which state, a high frequency power of a certain frequency is applied between the mounting table and the upper electrode, whereby a plasma of the processing gas is generated. By inducing the plasma thus generated to act on a semiconductor wafer, an etching processing or the like is carried out thereon.

In the above-described plasma processing apparatus, the upper electrode is provided at a position being directly exposed to the plasma and, as a result, a temperature thereof can increase beyond a desirable level. In order to overcome such drawback, a conventional plasma processing apparatus described in Japanese Patent Laid-Open Publication No. 1988-284820 (particularly see page 2-3 and FIG. 1) discloses therein coolant passageways for circulating a coolant, which are formed at an upper electrode so that the upper electrode can be cooled by circulating the coolant therethrough.

Another conventional plasma processing apparatus described in U.S. Pat. No. 4,534,816 (in particular see page 2-3 and FIGS. 1-6) discloses therein coolant passageways such as those explained above that are formed at an upper electrode and provided with a plurality of holes for uniformly distributing therethrough a processing gas toward a substrate to be processed.

As described above, in the conventional plasma processing apparatus, the upper electrode is cooled to stabilize a temperature thereof.

However, a recent trend of miniaturization of semiconductor device structure necessitates greater processing accuracy of a plasma processing apparatus. For this reason, it is required to further enhance an accuracy of controlling a temperature of an upper electrode and improving a uniformity of the temperature of the entire upper electrode in comparison with the conventional case.

Moreover, since the upper electrode is provided at the position directly exposed to the plasma, as described above, the upper electrode is consumed by the plasma. For this reason, the maintenance or repair of the upper electrode such as a regular replacement thereof and the like is required. However, a replacement of the entire upper electrode, including even the non-defective parts incurs high cost, resulting in an increase in an overall running cost. In order to minimize such increase in cost, only the part that is exposed to the plasma on the upper electrode is replaced, by detachably installing such part at the upper electrode.

However, in such case of the upper electrode being a detachable structure, thermal conductivity thereof deteriorates, and as a result there is a greater difficulty in controlling a temperature thereof with high accuracy.

### SUMMARY OF THE INVENTION

It is, therefore, an object of the present invention to provide a plasma processing apparatus and an upper electrode employed therein, which are capable of performing a plasma process with high accuracy and having an improved temperature controllability in comparison with a conventional one while reducing an overall running cost by reducing costs incurred by replacement parts for the upper electrode.

In accordance with a first aspect of the invention, there is provided an upper electrode facing a mounting table for mounting thereon a substrate to be processed, for use in generating a plasma of a processing gas between the mounting table and the upper electrode, including: a cooling block having therein a coolant path for circulating a coolant therethrough and one or more through holes for passing the processing gas therethrough; an electrode plate having one or more injection openings for injecting the processing gas toward the substrate to be processed mounted on the mounting table, the electrode plate being detachably fixed to a bottom surface of the cooling block via a thermally conductive member having flexibility; and an electrode frame installed at an upper portion of the cooling block and providing a processing gas diffusion gap for diffusing the processing gas between the cooling block and the electrode frame.

In accordance with a second aspect of the invention, there is provided an upper electrode facing a mounting table for mounting thereon a substrate to be processed, for use in generating a plasma of a processing gas between the mounting table and the upper electrode, including: a cooling block having one or more through holes for passing the processing gas therethrough and a cooling passage for circulating a coolant therethrough, the cooling passage being configured to be provided near each of the through holes, wherein portions of the coolant path provided at inner peripheral portions of the cooling block inside an outermost peripheral portion of the coolant path are bent such that a maximum length of a straight portion thereof corresponds to about 3 pitches of the through holes, wherein the coolant path has one or more coolant passageways to establish one or more cooling systems and a coolant is introduced toward a central portion of the cooling block through each coolant passageway and then gradually flows outward in a serpentine shape.

In accordance with a third aspect of the invention, there is provided a plasma processing apparatus including an upper electrode disclosed in the first aspect of the invention.

In accordance with a fourth aspect of the invention, there is provided a plasma processing apparatus including an upper electrode of the second aspect of the invention.

### BRIEF DESCRIPTION OF THE DRAWINGS

The above and other objects and features of the present invention will become apparent from the following description of preferred embodiments, given in conjunction with the accompanying drawings, in which:

FIG. 1 shows an overall schematic configuration of a plasma processing apparatus in accordance with a first preferred embodiment of the present invention;

FIG. 2 illustrates a schematic configuration of a main part of the plasma processing apparatus shown in FIG. 1; and

FIG. 3 describes a schematic configuration of another main part of the plasma processing apparatus shown in FIG. 1.

### DETAILED DESCRIPTION OF THE PREFERRED EMBODIMENTS

Hereinafter, preferred embodiments of the present invention will be described with reference to the accompanying drawings.

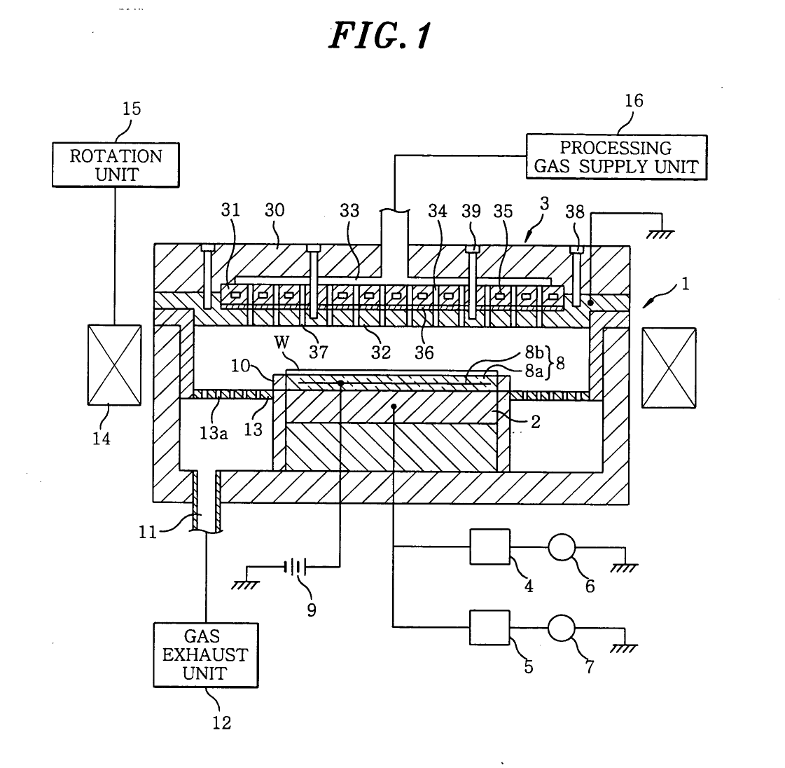

Referring to FIG. 1, there is schematically illustrated a configuration of a preferred embodiment in which the present invention is applied to a plasma etching apparatus for etching a semiconductor wafer. As shown in FIG. 1, a reference numeral 1 represents a cylindrical vacuum chamber, made of, e.g., aluminum, which can be hermetically sealed.

Installed in the vacuum chamber 1 is a mounting table 2 for mounting thereon a semiconductor wafer W, which also serves as a lower electrode. Furthermore, installed at a ceiling portion of the vacuum chamber 1 is an upper electrode 3, which makes up a shower head. The mounting table 2 (the lower electrode) and the upper electrode 3 form a pair of parallel plate electrodes. A structure of the upper electrode 3 will be described later.

The mounting table 2 is connected with two high frequency power supplies 6 and 7 via respective matching units 4 and 5, so that a high frequency power of two predetermined frequencies (e.g., 100 MHz and 3.2 MHz) can be superposed and supplied to the mounting table 2. However, a single high frequency power may be supplied to the mounting table 2 by using a singly high frequency power supply.

Provided on a mounting surface of the mounting table 2 is an electrostatic chuck 8 for attracting and maintaining the semiconductor wafer W. The electrostatic chuck 8 includes an insulating layer 8a and an electrostatic chuck electrode 8b embedded in the insulating layer 8a, wherein the electrostatic chuck electrode 8b is connected to a DC power supply 9. In addition, a focus ring 10 is installed at an upper periphery of the mounting table 2 around the semiconductor wafer W.

Installed at a bottom portion of the vacuum chamber 1 is a gas exhaust port 11 connected to a gas exhaust unit 12 which includes a vacuum pump and the like.

The mounting table 2 is surrounded by a ring-shaped gas exhaust ring 13 which is made of a conductive material and is provided with a plurality of through holes 13a. The gas exhaust ring 13 is grounded. Further, the vacuum chamber 1 can be set to a predetermined vacuum level by the gas exhaust unit 12, which evacuates the vacuum chamber 1 through the gas exhaust port 11 via the gas exhaust ring 13.

In addition, a magnetic field forming mechanism 14 is installed around the vacuum chamber 1 to form a desired magnetic field in a processing space of the vacuum chamber 1 and is provided with a rotation unit 15. The rotation unit 15 rotates the magnetic field forming mechanism 14 around the vacuum chamber 1 to rotate a magnetic field formed in the vacuum chamber 1.

Hereinafter, a configuration of the aforementioned upper electrode 3 will be described. As shown in FIG. 3, the upper electrode 3 of an approximate disc shape includes as main parts an electrode frame 30, a cooling block 31 installed under the electrode frame 30 and an electrode plate 32 installed under the cooling block 31.

The electrode plate 32 provided at a lowermost portion of the upper electrode 3 is exposed to a plasma and therefore is consumed by the plasma. For this reason, the electrode plate 32 is detachably installed. Specifically, by separating and replacing only the electrode plate 32 from the upper electrode 3, costs incurred by replacement parts are reduced, which in turn significantly reduces the overall running cost. Further, the coolant path 35 provided in the cooling block 31 (as will be described later) raises the manufacturing cost of the cooling block 31. Accordingly, by detachably installing the cooling block 31 and the electrode plate 32, which in turn allows only the electrode plate 32 to be replaced, the cost of the replacement parts can be reduced.

Formed between the electrode frame 30 and the cooling block 31 is a processing gas diffusion gap 33 for diffusing a processing gas introduced through an upper portion of the electrode frame 30 from a processing gas supply unit 16.

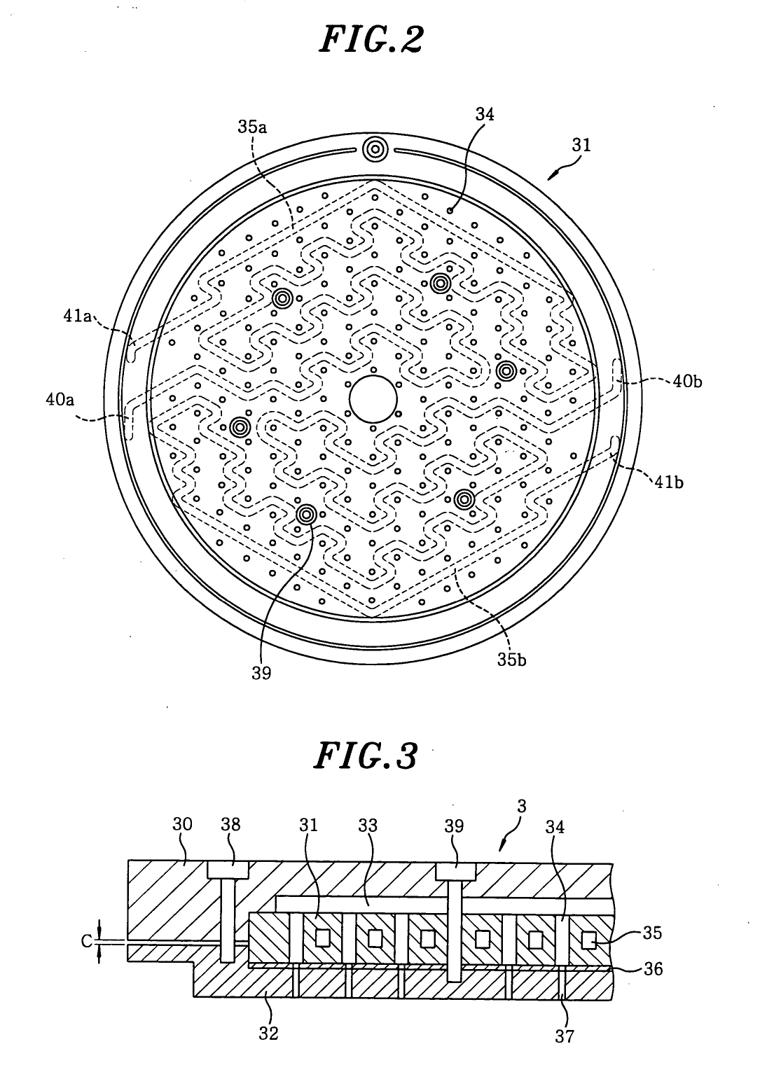

Provided at the cooling block 31 is a plurality of through holes 34 for passing therethrough the processing gas from the processing gas diffusion gap 33. Provided between the through holes 34 is the coolant path 35 for circulating a coolant therethrough, wherein the coolant path 35 is minutely bent in serpentine shape, as illustrated in FIG. 2.

The electrode plate 32 is detachably fixed to a lower portion of the cooling block 31 via a thermally conductive member having flexibility, e.g., a high thermal conductive silicone rubber sheet 36. Furthermore, the electrode plate 32 is provided with a plurality of injection openings 37 for injecting the processing gas such that respective injection openings 37 correspond to the respective through holes 34 provided at the cooling block 31, wherein the injection openings and the through holes 34 are same in number. Moreover, formed at the silicone rubber sheet 36 are openings (not shown) corresponding to the injection openings 37 and the through holes 34.

The electrode frame 30, the cooling block 31 and the electrode plate 32 are fixed as one body by a plurality of outer peripheral clamping screws 38 and inner peripheral clamping screws 39. The outer and the inner peripheral clamping screws 38 and 39 are equi-distanced respectively around the circumference of the upper electrode 3, wherein the inner peripheral clamping screws 39 are placed at a radially inner region than the outer peripheral clamping screws 38. The outer and the inner peripheral clamping screws 38 and 39 are screwed from an upper portion of the electrode frame 30 into the electrode plate 32, which lift the electrode plate 32 upward, so that the cooling block 31 is fixedly interposed between the electrode frame 30 and the electrode plate 32. Moreover, as illustrated in FIG. 3, a clearance C (e.g., equal to or greater than 0.5 mm) is created between the electrode frame 30 and the electrode plate 32 so that the torque of the screws 38 and 39 can be securely applied therebetween and the electrode plate 32 can be in proper contact with the cooling block 31.

As described above, in this embodiment, the processing gas diffusion gap 33 is formed above the cooling block 31, and the processing gas diffused thereinto is injected in such a manner as to be uniformly distributed via the through holes 34 formed at the cooling block 31 and the injection openings 37 formed at the electrode plate 32.

Accordingly, the cooling block 31 and the electrode plate 32 can be closely arranged and further be in a surface. This allows the cooling block 31 to effectively and uniformly cool the electrode plate 32. In addition, since the high thermal conductive silicone rubber sheet 36 having flexibility is installed between the cooling block 31 and the electrode plate 32, tight coupling therebetween can be achieved in comparison with a case where the cooling block 31 made of a hard material is directly in contact with the electrode plate 32 (made of, e.g., aluminum). As a result, the thermal conductivity therebetween can be enhanced, and the electrode plate 32 can be effectively and uniformly cooled by the cooling block 31. Further, the cooling block 31 and the electrode plate 32 are engaged with each other by the inner peripheral clamping screws 39 and the outer peripheral clamping screws 38, thereby preventing a degradation in the tight coupling between the cooling block 31 and the electrode plate 32, e.g., by a distortion due to a thermal expansion.

Further, in this embodiment, the coolant path 35 formed at the cooling block 31 is configured to have, e.g., a dual system including a coolant passageway 35a for circulating a coolant through approximately half a portion (an upper portion as shown in FIG. 2) of the cooling block 31 and a coolant passageway 35b for circulating a coolant through a remaining approximately half a portion (a lower portion as shown in FIG. 2) thereof. Such coolant passageway 35a and 35b of the dual system are symmetrically formed. Furthermore, a coolant entrance 40a and a coolant exit 41a of the coolant passageway 35a and a coolant entrance 40b and a coolant exit 41b of the coolant passageway 35b are disposed at opposite positions, which are at an approximately 180 degree apart. By forming the coolant passageways 35a and 35b of the dual system, it is possible to effectively, uniformly control the total temperature of the electrode plate 32.

The coolant introduced from the coolant entrances 40a and 40b flows from the opposite directions toward a central portion of the cooling block 31. The coolant flows in an outward serpentine shape through the coolant passageways 35a and 35b, after which the coolant is discharged to the outside through the coolant exits 41a and 41b. Since the coolant introduced from the coolant entrances 40a and 40b flows toward a central portion of the cooling block 31, it is easy to generate a high-density plasma and suppress an increase in temperature at the central portion of the electrode plate 32 which has high likelihood of rising temperature. As a result, a temperature control can be uniformly carried out.

The coolant passageways 35a and 35b are arranged so as to pass a near portion of every through hole 34 formed at the cooling block 31. Further, in the coolant passageways 35a and 35b, coolant passageways adjacent to each other in which there are one or more through holes 34 therebetween have an opposite coolant circulating direction. Due to such flow of the coolant, a temperature of the entire electrode plate 32 can be more effectively and uniformly controlled.

The coolant passageways 35a and 35b excluding those at the outer most periphery of the coolant block 31, i.e., only those inside the outer most periphery of the coolant path 35, are formed as a minutely bent structure in such a manner that no straight portion thereof is longer than about 3 pitches of through holes 34. Further, in this embodiment, a pitch of two through holes 34 [a distance between respective centers of two adjacent through holes 34] is set to be 15 mm. In this case, a pitch of two injection openings 37 of the electrode plate 32 is also the same as that of two through holes 34.

Due to the minutely bent structure of the coolant passageways 35a and 35b, the coolant can be sufficiently mixed while circulating therethrough, thereby enabling a more effective temperature control.

Hereinafter, an etching process in a plasma etching apparatus having the above-described configuration will now be described.

First, a gate valve (not illustrated) provided at a loading/unloading opening (not shown) of the vacuum chamber 1 is opened, so that a semiconductor wafer W can be loaded into the vacuum chamber 1 by a transfer mechanism (not shown) and then mounted on the mounting table 2. Thereafter, the semiconductor wafer W mounted on the mounting table 2 is attracted and maintained thereon by applying a predetermined DC power from the DC power supply 9 to the electrostatic chuck electrode 8b of the electrostatic chuck 8.

Next, after the transfer mechanism is withdrawn from the vacuum chamber 1, the gate valve is closed and then the vacuum chamber 1 is evacuated by the vacuum pump of the gas exhaust unit 12. When the vacuum chamber 1 is under a certain vacuum level, an etching processing gas having a flow rate of, e.g., 100 to 1000 sccm, is introduced into the vacuum chamber 1 via the gas diffusion gap 33, the through holes 34 and the injection openings 37. Then, the vacuum chamber 1 is maintained under a pressure, e.g., 1.3 to 133 Pa (10 to 1000 mTorr).

In this state, a high frequency power of frequencies (e.g., 100 MHz and 3.2 MHz) is supplied from the respective high frequency power supplies 6 and 7 to the mounting table 2.

As described above, by applying the high frequency power to the mounting table 2, a high frequency electric field is formed at a processing space between the upper electrode 3 and the mounting table 2 (the lower electrode). Further, a certain magnetic field is formed in the processing space by the magnetic field forming mechanism 14. Accordingly, the processing gas supplied to the processing space is converted into a plasma, and a certain film on the semiconductor wafer W is etched by the plasma.

At this time, the upper electrode 3 is heated by a heater (not shown) installed in the upper electrode 3 to a temperature (e.g., 60° C.). When the plasma is generated, the heater stops heating. Then, by circulating the coolant such as a cooling material and the like through the coolant passageways 35a and 35b, a temperature of the upper electrode 3 is controlled at a certain temperature. As described in this embodiment, since the temperature of the upper electrode 3 can be uniformly controlled with high accuracy, a desired etching process can be performed with high accuracy by using the stable and uniform plasma.

As an example, the etching of the semiconductor wafer W was carried out under following conditions: processing gases of C₄F₆/Ar/O₂ each having a flow rate of 30/1000/35 sccm; a pressure of 6.7 Pa (50 mTorr); and a power of HF/LF each being 500/4000 W. In this case, temperatures of various portions such as a central portion and a peripheral portion of the upper electrode 3 were measured in which the respective temperatures were controlled that a difference therein ranges within about 5° C.

After performing a certain etching process, a supply of the high frequency power from the high frequency power supplies 6 and 7 and the etching process are stopped. Then, an unloading process of the semiconductor wafer W from the vacuum chamber 1 is performed in a reverse sequence of the loading process.

Although this embodiment has described a case where the present invention is applied to the plasma etching apparatus for etching the semiconductor wafer, it is not limited thereto. For example, the present invention can be applied to an apparatus for processing a substrate other than the semiconductor wafer and further to an apparatus for performing a film forming process such as CVD and the like other than the etching process.

As described above, in accordance with the plasma processing apparatus and the upper electrode employed therein of the present invention, the temperature controllability can be improved while reducing a running cost by decreasing the cost incurred by parts therefor and, further, the plasma processing can be performed with high accuracy.

While the invention has been shown and described with respect to the preferred embodiments, it will be understood by those skilled in the art that various changes and modifications may be made without departing from the spirit and scope of the invention as defined in the following claims.

1. An upper electrode facing a mounting table for mounting thereon a substrate to be processed, for use in generating a plasma of a processing gas between the mounting table and the upper electrode, comprising:
a cooling block including therein a coolant path for circulating a coolant therethrough and one or more through holes for passing the processing gas therethrough;
an electrode plate including one or more injection openings for injecting the processing gas toward the substrate to be processed mounted on the mounting table, the electrode plate being detachably fixed to a bottom surface of the cooling block via a thermally conductive member having flexibility; and
an electrode frame installed at an upper portion of the cooling block and providing a processing gas diffusion gap for diffusing the processing gas between the cooling block and the electrode frame.

2. The upper electrode of claim 1, wherein the coolant path is bent inside the cooling block to be located adjacent to each of the through holes.

3. The upper electrode of claim 2, wherein portions of the bent coolant path adjacent to each other have an opposite coolant flow direction.

4. The upper electrode of claim 3, wherein portions of the coolant path provided at inner peripheral portions of the cooling block inside an outermost peripheral portion of the coolant path are bent such that a maximum length of a straight portion thereof corresponds to about 3 pitches of the through holes.

5. The upper electrode of claim 1, wherein the coolant path has one or more coolant passageways to establish one or more cooling systems.

6. The upper electrode of claim 5, wherein a coolant is introduced toward a central portion of the cooling block through each coolant passageway and then gradually flows outward in a serpentine shape.

7. The upper electrode of claim 5, wherein the electrode plate is formed in a disc shape and fixed to the cooling block by one or more outer peripheral clamping screws installed at an outer peripheral portion of the electrode plate and one or more inner peripheral clamping screws provided at an inner portion than a location of the outer peripheral clamping screws.

8. The upper electrode of claim 7, wherein the outer and the inner peripheral clamping screws are screwed into the electrode plate from an upper portion of the electrode frame so that the cooling block is fixedly interposed between the electrode frame and the electrode plate.

9. The upper electrode of claim 8, wherein a clearance is provided between the electrode frame and the electrode plate, and the electrode frame, the cooling block and the electrode plate are fixed as one body while the cooling block and the electrode plate are pressed together.

10. An upper electrode facing a mounting table for mounting thereon a substrate to be processed, for use in generating a plasma of a processing gas between the mounting table and the upper electrode, comprising:
a cooling block including one or more through holes for passing the processing gas therethrough and a cooling passage for circulating a coolant therethrough, the cooling passage being configured to be provided near each of the through holes,
wherein portions of the coolant path provided at inner peripheral portions of the cooling block inside an outermost peripheral portion of the coolant path are bent such that a maximum length of a straight portion thereof corresponds to about 3 pitches of the through holes, and
wherein the coolant path has one or more coolant passageways to establish one or more cooling systems and a coolant is introduced toward a central portion of the cooling block through each coolant passageway and then gradually flows outward in a serpentine shape.

11. A plasma processing apparatus comprises an upper electrode disclosed in claim 1.

12. A plasma processing apparatus comprises an upper electrode disclosed in claim 10.
